(19) United States
(12) Patent Application Publication
(10) Pub. No.: US 2026/0076161 A1
(43) Pub. Date: Mar. 12, 2026

(54) CONDUCTIVE INTERCONNECTION STRUCTURE AND MANUFACTURING METHOD THEREOF

(71) Applicant: Taiwan Semiconductor Manufacturing Company, Ltd., Hsinchu (TW)

(72) Inventors: Hwei-Jay CHU, Hsinchu (TW); Hsi-Wen TIEN, Hsinchu (TW); Wei-Hao LIAO, Hsinchu (TW); Yu-Teng DAI, Hsinchu (TW); Hsin-Chieh YAO, Hsinchu (TW); Cheng-Hao CHEN, Hsinchu (TW); Wei Chih WANG, Hsinchu (TW); Chih Wei LU, Hsinchu (TW)

(73) Assignee: Taiwan Semiconductor Manufacturing Company, Ltd., Hsinchu (TW)

(21) Appl. No.: 18/827,050

(22) Filed: Sep. 6, 2024

(51) Int. Cl. H01L 21/768; H01L 23/522

(52) U.S. Cl. CPC H10W 20/056; H10W 20/089; H10W 20/42

(57) ABSTRACT

A conductive interconnection structure includes a conductive feature part, a dielectric structure, a trench filling portion, a via portion and a metal layer. The dielectric structure is formed over the conductive feature part. The dielectric structure includes a first dielectric layer and a second dielectric layer stacked on each other. The second dielectric layer covers the first dielectric layer. The trench filling portion is embedded in the dielectric structure, and the trench filling portion and the second dielectric layer have different etching selectivities. The via portion is located in the first dielectric layer at the bottom surface of the trench filling portion. The metal layer penetrates the dielectric structure, the trench filling portion and the via portion, and the bottom surface of the metal layer is electrically connected to the conductive feature part.

### BACKGROUND

The semiconductor integrated circuit (IC) industry has experienced rapid growth. Technological advances in IC materials and design have produced continuous improvements in generations of ICs. Each generation has smaller and more complex circuits than the previous generation. However, these advances have increased the complexity of processing and manufacturing ICs.

Since the feature sizes continue to decrease, fabrication processes continue to become more difficult to perform. Thus, there is a challenge to form reliable semiconductor devices with smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 9 respectively illustrate schematic cross-sectional views of a method for manufacturing a conductive interconnect structure according to an embodiment of the present disclosure.

FIGS. 10A to 10D respectively illustrate a schematic plan view, a schematic cross-sectional view of A-A′, a schematic cross-section B-B′ and a schematic cross-section C-C′ of a conductive interconnection structure according to another embodiment of the present disclosure.

FIGS. 11A to 11D respectively illustrate a schematic plan view, a schematic diagram along the X-X′ cross-section, a schematic diagram along the Y-Y′ cross-section and a schematic diagram along the Z-Z′ cross-section of a conductive interconnection structure according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

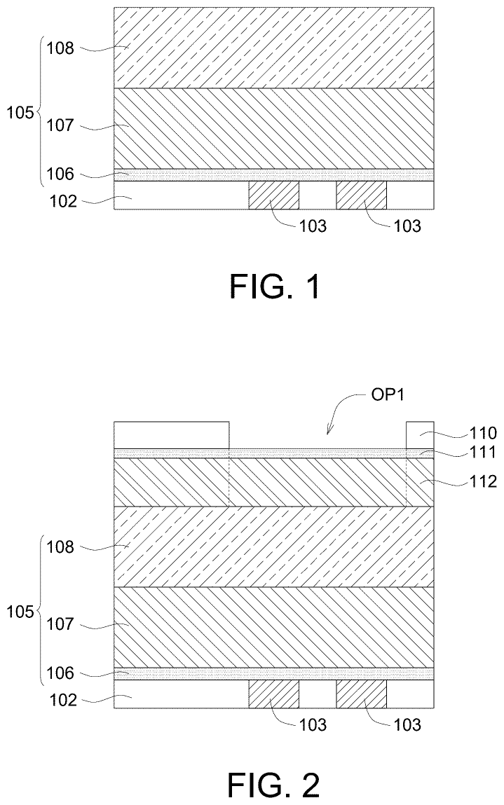

FIGS. 1 to 9 respectively illustrate schematic cross-sectional views of a manufacturing method of the conductive interconnection structure 100 according to an embodiment of the present disclosure.

IC manufacturing processes can generally be divided into three categories: front-end-of-line (FEOL) process, middle-end-of-line (MEOL) process, and back-end-of-line (BEOL) process. FEOL process generally encompasses processes related to the manufacture of IC devices such as transistors. For example, FEOL process may include forming isolation structures for isolating IC devices, gate structures, and forming source and drain structures (also referred to as a source/drain structure) of a transistor. MEOL generally encompasses processes related to the fabrication of connection structures (also known as contacts or plugs) that connect to conductive feature parts (or conductive areas) of IC devices. For example, MEOL process may include forming a connection structure connected to a gate structure and a connection structure connected to a source/drain structure. BEOL process generally covers processes related to the fabrication of multi-layer interconnect (MLI) structures that electrically connect IC devices and connection structures manufactured by FEOL and MEOL processes. Therefore, the operation of the IC device can be realized. As mentioned above, process scaling has increased the complexity of processing and manufacturing ICs. For example, in some comparison methods, ruthenium (Ru) (which has a smaller resistivity) is used to form the connection structure formed by MEOL in order to reduce the plug contact resistance, but the connection structure containing Ru has presented yield and cost challenges, this is because the connection structure becomes more compact as the size of IC components continues to shrink.

Referring to FIG. 1, a dielectric structure 105 is formed over a semiconductor substrate 102 and a conductive feature part 103. The dielectric structure 105 includes a first dielectric layer 107 and a second dielectric layer 108 stacked on each other. The first dielectric layer 107 covers on the second dielectric layer 108, and the first dielectric layer 107 and the second dielectric layer 108 include same or different dielectric materials.

In one embodiment, the semiconductor substrate 102 may be a silicon substrate, silicon on an insulating layer, or other semiconductor materials. The dielectric structure 105 may be dielectric layers composed of multiple materials covering the semiconductor substrate 102, for example, a silicon oxide layer, a silicon nitride layer, silicon nitride carbide, a low dielectric coefficient (LK) material layer, ultra-low dielectric coefficient (ULK) material layer or any combination of the above materials. The semiconductor substrate 102 may include a conductive feature part 103 disposed therein. In some embodiments, the conductive feature part 103 may be a FEOL component, such as the metal gate or the source/drain region. In some embodiments, the conductive feature part 103 may be a MEOL component, such as a contact of a connecting structure. In other embodiments, the conductive feature part 103 may be a BEOL component, such as a metal wire.

Alternatively, the conductive feature part 103 may be a silicide feature disposed on a source, drain or gate electrode typically from a sintering process introduced by at least one of the processes including thermal heating, laser irradiation or ion beam mixing. The silicide feature may be formed on polysilicon gate (typically known as “polycide gate”) or on source/drain (typically known as “salicide”) by a self-aligned silicide technique. In another embodiment, the conductive feature part 103 may include an electrode of a capacitor or one end of a resistor.

In some embodiments, the semiconductor substrate 102 includes silicon. Alternatively or additionally, the semiconductor substrate 102 includes: another elemental semiconductor, such as germanium; a compound semiconductor, such as silicon carbide, gallium arsenide, gallium phosphide, indium phosphide, indium arsenide and/or indium antimonide; an alloy semiconductor, such as silicon germanium (SiGe), GaAsP, AlInAs, AlGaAs, GaInAs, GaInP and/or GaInAsP; or combinations thereof. In some embodiments, the semiconductor substrate 102 includes one or more Group III-V materials, one or more Group II-IV materials, or a combination thereof. In some embodiments, the semiconductor substrate 102 is a semiconductor-on-insulator substrate, such as a silicon on insulator (SOI) substrate, a silicon germanium on insulator (SGOI) substrate, or a germanium on insulator (GOI) substrate. The semiconductor-on-insulator substrates may be fabricated using separation of implanted oxygen (SIMOX), wafer bonding, and/or other suitable methods. The semiconductor substrate 102 may include various doped regions (not shown) configured according to design requirements of a device, such as p-type doped regions, n-type doped regions, or combinations thereof. The P-type doped region (e.g., p-type well) includes a p-type dopant, such as boron, indium, another p-type dopant, or a combination thereof. The N-type doped region (e.g., n-type well) includes an n-type dopant, such as phosphorus, arsenic, another n-type dopant, or a combination thereof. In some implementations, the semiconductor substrate 102 includes doped regions formed using a combination of p-type dopants and n-type dopants. Various doped regions may be directly formed on and/or in the semiconductor substrate 102, such as providing a p-well structure, an n-well structure, a double-well structure, a protruding structure, or a combination thereof. An ion implantation process, a diffusion process, and/or another suitable doping process may be performed to form various doped regions.

As shown in FIG. 1, the dielectric structure 105 can cover the semiconductor substrate 102 and the conductive feature part 103. In some embodiments, dielectric structure 105 may be referred to as an inter-layer dielectric (ILD) layer. In some embodiments, dielectric structure 105 may be referred to as an inter-layer dielectric (ILD) layer or an inter-metal dielectric (IMD) layer.

In some embodiments, before forming the first dielectric layer 107, a contact etch stop layer (CESL) 106 may be formed on the semiconductor substrate 102. The contact etch stop layer (CESL) 106 may include silicon oxide, silicon nitride, silicon carbide, silicon oxynitride, silicon oxycarbide, silicon carbon oxynitride, aluminum oxynitride, aluminum oxide, or the like. The first dielectric layer 107 is formed on the contact etch stop layer (CESL) 106. The first dielectric layer 107 may include silicon oxide, silicon nitride, silicon carbide, silicon oxynitride, silicon oxynitride, silicon carbon oxynitride, or the like. The second dielectric layer 108 is formed on the first dielectric layer 107. The second dielectric layer 108 may include silicon carbide, silicon oxycarbide, and the like. The contact etch stop layer (CESL) 106 has a thickness of approximately 10 to 300 Å. The thickness of the first dielectric layer 107 is approximately 30 to 1000 Å, and the thickness of the second dielectric layer 108 is approximately 30 to 1000 Å.

The first dielectric layer 107 and the second dielectric layer 108 may include SiOx, SiOxCyHz, SiOxCy, SiCx or related low-k value materials with ordered pores or non-pores. The term “ordered pores” as used herein refers to a defined arrangement of air-filled pores or air gaps formed within a dielectric material. The interlayer dielectric layer with ordered pores has the characteristics of low dielectric constant and high mechanical strength. In some embodiments, the interlayer dielectric layers 107 and 108 may be formed by chemical vapor deposition (CVD), physical vapor deposition (PVD), atomic layer deposition (ALD), spin coating, or other appropriate processes at a temperature between 450 degrees Celsius and 300 degrees Celsius. In some embodiments, an additional annealing or ultraviolet (UV) curing process may be performed to form the interlayer dielectric layer, but may not be required.

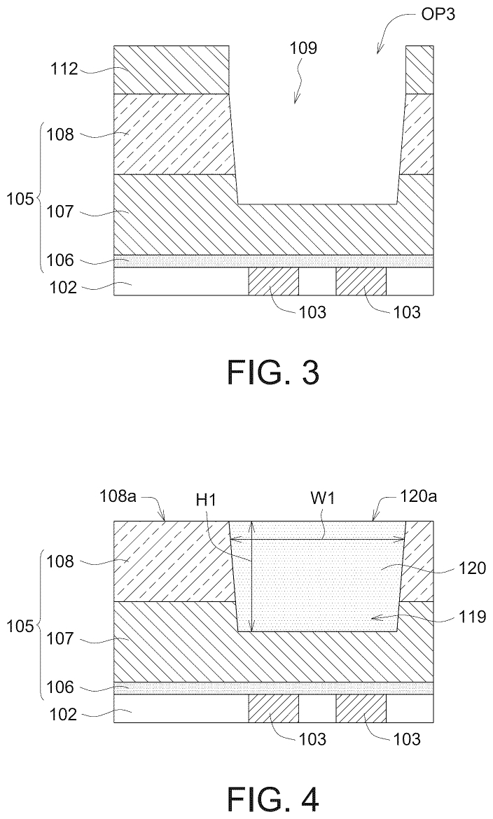

Referring to FIG. 2, at least one patterned photoresist layer 110-112 is formed on the dielectric structure 105 to expose part of the dielectric structure 105 in the openings of the patterned photoresist layers 110-112. The opening size of the patterned photoresist layers 110-112 is used to define the size of the dielectric structure 105 to be etched. The various stages of the patterning process include the following. First, the uppermost first photoresist layer 110 is patterned to form a first opening OP1 in the first photoresist layer 110, and the first opening OP1 exposes the middle second photoresist layer 111. Next, the second photoresist layer 111 is patterned to form a second opening in the second photoresist layer 111, and the second opening exposes the lowermost third photoresist layer 112. Next, the third photoresist layer 112 is patterned to form a third opening OP3 (see FIG. 3) in the third photoresist layer 112. The above-mentioned patterned photoresist layers 110-112 can have opening patterns transferred thereon through an exposure and development process. The commonly used is a three-layer photoresist structure, but the disclosure is not limited thereto.

The third photoresist layer 112 is a bottom photoresist coated on the second dielectric layer 108, which can prevent the second dielectric layer 108 from reflecting a significant amount of incident radiation and negatively affecting the quality of the pattern during the photoresist exposure. The second photoresist layer 111 is an intermediate layer formed on the bottom photoresist. The second photoresist layer 111 is, for example, a silicon-containing resin polymer, which has a better etching selectivity, so that the line width uniformity (i.e., critical dimension uniformity) of after etching inspection (AEI) is better. The third photoresist layer 112 is, for example, a photosensitive layer, and its exposure can use KrF/ArF light source (248 nm/193 nm) and EUV (13.5 nm) or charged particle beam (such as e-beam or ion-beam). Exposure methods can use immersion or dry (non-immersion) lithography techniques.

Photo masks can be used during exposure, such as binary photo masks, phase shift masks (PSM), attenuated phase shift masks (APSM), transmission type reticle or EUV reflective reticle to define exposed and unexposed areas. In another embodiment, the desired pattern may be overwritten directly on the dielectric structure 105 using a charged particle beam that does not require a photomask.

Referring to FIG. 3, the dielectric structure 105 is etched to form a first opening 109 in the dielectric structure 105. The first opening 109 penetrates the second dielectric layer 108 and exposes a portion of the first dielectric layer 107. In some embodiments, the first opening 109 may be formed using a lithography operation with a masking technique and an anisotropic etching operation (e.g., plasma etching or reactive ion etching), but the present disclosure is not limited thereto. Anisotropic etching conditions include the following: Power: 100-2000 W/bias: 0-1200 W, and the reaction gas includes at least one material selected from HBr, Cl₂, H₂, CH₄, N₂, He, Ne, Kr, CF₄, CHF₃, CH₃F, CH₂F₂, C₄F₈, C₄F₆, SF₆, N₂, O₂ and Ar. In some embodiments, the dielectric structure 105 is anisotropically etched to form trenches with predetermined opening sizes, and the opening patterns are, for example, rectangular, circular, or other patterns. The first opening 109 is used to define the depth H1 and width W1 of a trench filling portion 120 (see FIG. 4) intended to be filled with dielectric material.

Referring to FIG. 4, a trench filling material 119 is filled in the first opening 109 to form a trench filling portion 120. The trench filling material 119 and the second dielectric layer 108 have different etching selectivity. In some embodiments, the etch selectivity ratio of trench filling material 119 relative to second dielectric layer 108 may be greater than 5, such as greater than 7 or higher. After the trench filling material 119 is filled into the first opening 109, a planarization process may be performed to expose the top surface 108a of the second dielectric layer 108 and the top surface 120a of the trench filling portion 120. In one embodiment, excess trench filling material 119 is removed, such as by chemical mechanical polishing (CMP), so that the top surface 108a of the second dielectric layer 108 and the top surface 120a of the trench filling portion 120 are coplanar.

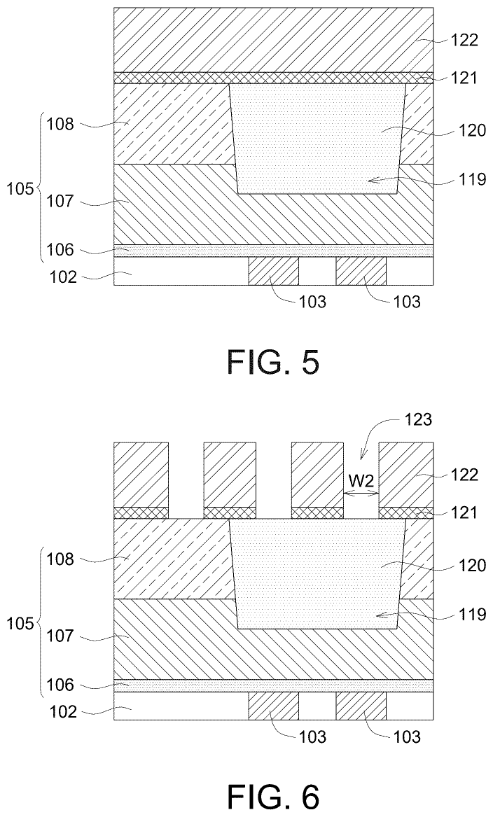

Referring to FIG. 5, a hard mask layer 122 is formed on the planarized second dielectric layer 108 and the trench filling portion 120. Before forming the hard mask layer 122, an etch stop layer 121 may be optionally formed on the planarized surface. The etch stop layer 121 may include silicon oxide, silicon nitride, silicon carbide, or the like, and may be formed by CVD, PECVD, ALD, or any suitable deposition technique. The hard mask layer 122 may be TiN, TiO, W, WdC, HfO, ZrO, ZnO, TiZrO, SiC, SiO₂, SiOC, SiN, SiCN, SiON, SiOCN, AlOx, AlON, or the like, and may be Formed by CVD, PECVD, ALD or any suitable deposition technique. The thickness of hard mask layer 122 is approximately 30 to 500 Å.

Referring to FIG. 6, the hard mask layer 122 is patterned to form at least one patterned opening 123. The patterned opening 123 is used to define the width W2 of at least one trench. Next, the etch stop layer 121 not covered by the hard mask layer 122 is removed to expose the second dielectric layer 108 and the trench filling portion 120. The etching of the hard mask layer 122 and the etch stop layer 121 may use a lithography operation with a masking technique and an anisotropic etching operation (e.g., plasma etching or reactive ion etching), but the present disclosure is not limited thereto.

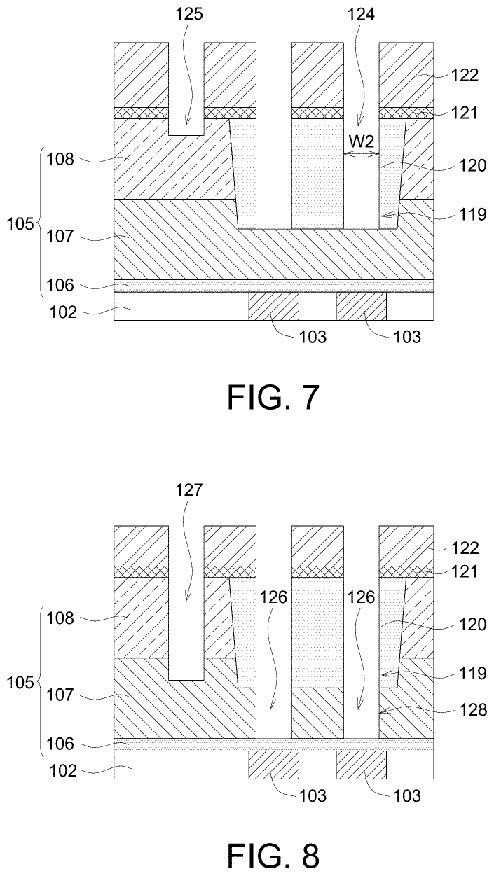

Referring to FIG. 7, the trench filling material 119 is etched to form a second opening 124 in the trench filling portion 120. The second opening 124 exposes the first dielectric layer 107 at the bottom surface of the trench filling portion 120. In this embodiment, when the trench filling material 119 is etched by the plasma or ion beam, the etching rate of the second dielectric layer 108 by the plasma or ion beam is lower than that of the trench filling portion 120 by the plasma or ion beam, so the second opening 124 with a high aspect ratio can be formed in the trench filling portion 120, and the recess 125 with a shallow aspect ratio can be formed in the second dielectric layer 108. The width W2 of the second opening 124 is substantially the same as the width W2 of the trench. The second opening 124 is used to define the depth H1 and width W2 of a conductive trace to be formed. The depth H1 of the trench filling portion 120 is substantially equal to the depth of the conductive traces intended to be formed.

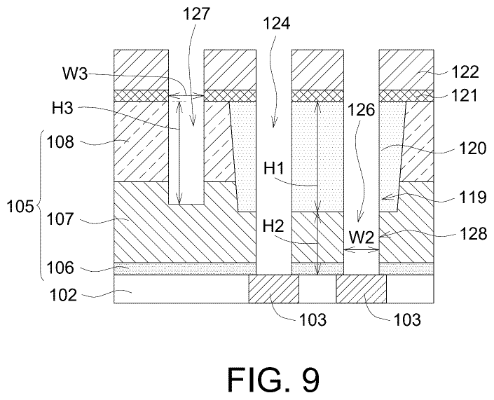

Referring to FIG. 8, the first dielectric layer 107 exposed in the second opening 124 is etched to form a third opening 126 in the first dielectric layer 107. The third opening 126 may be formed using anisotropic etching (e.g., plasma etching or reactive ion etching) or wet etching, but the present disclosure is not limited thereto. When the plasma or ion beams etch the first dielectric layer 107 exposed in the second opening 124, the second dielectric layer 108 exposed in the patterned opening 123 may be etched simultaneously to form a fourth opening 127 in the second dielectric layer 108. Referring to FIG. 9, the depth H3 of the fourth opening 127 is smaller than the sum of the depths of the second opening 124 and the third opening 126 (i.e., H1+H2). The fourth opening 127 and the third opening 126 may be formed simultaneously or separately. The third opening 126 is used to define the depth H2 and width W2 of the conductive pillar intended to be formed. The fourth opening 127 is used to define the depth H3 and width W3 of another conductive trace (i.e., 133) to be formed.

As shown in FIG. 9, in some embodiments, the etch selectivity ratio of the trench filling portion 120 relative to the first dielectric layer 107 may be greater than 5, such as greater than 7 or higher. When the plasma or ion beams etch the first dielectric layer 107 exposed in the second opening 124, the trench filling portion 120 will not be etched twice by the plasma or ion beams. In addition, when the etching selectivities of the first dielectric layer 107 and the second dielectric layer 108 are substantially the same or similar, the plasma or ion beams can simultaneously etch the first dielectric layer 107 and the second dielectric layer 108. However, the trench filling portion 120 will not be affected. In another embodiment, when the etching selectivities of the first dielectric layer 107 and the second dielectric layer 108 are different, the first dielectric layer 107 and the second dielectric layer 108 can be etched separately.

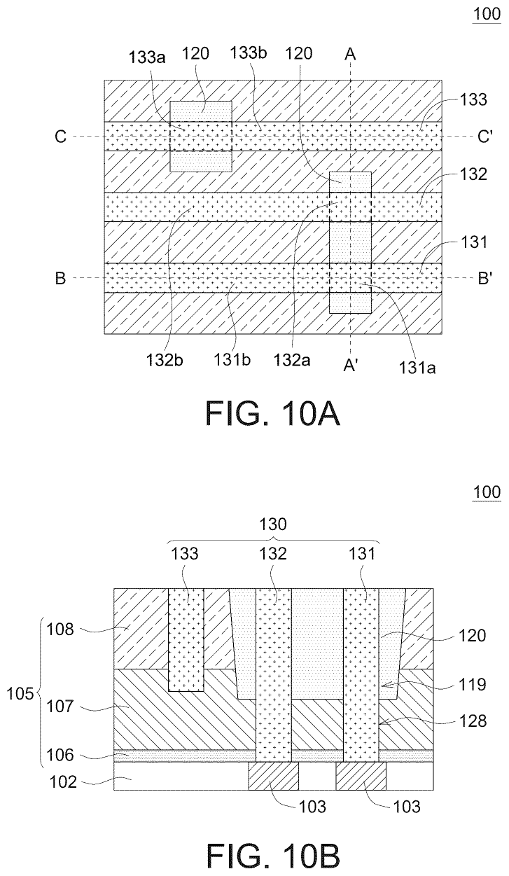

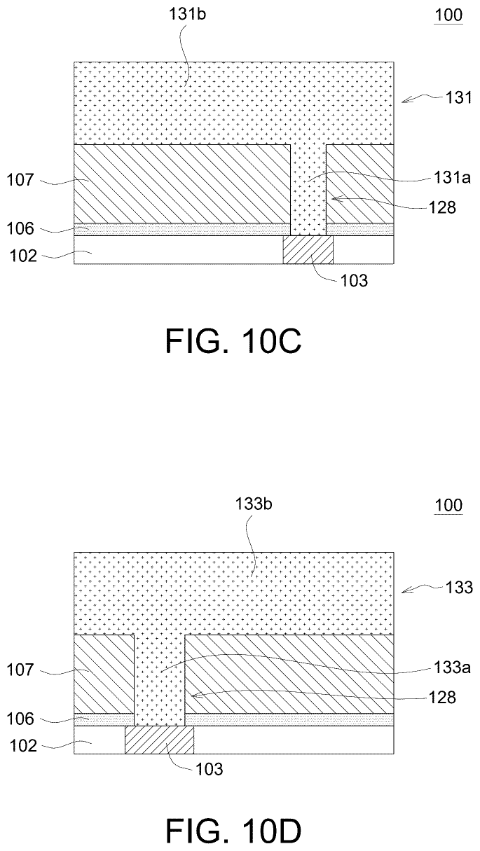

In addition, in FIG. 9, after the first dielectric layer 107 is etched, the contact etch stop layer 106 not covered by the first dielectric layer 107 can be further removed to expose the conductive feature parts in the third opening 126. The third opening 126 is used to define a depth H2 and a width W2 of a via portion 128 for at least one metal layer 130 to be filled in the second opening 124 and the third opening 126. As shown in FIG. 10B, a first metal layer 131 is formed in the second opening 124 and the third opening 126, and the bottom surface of the first metal layer 131 is electrically connected to the conductive feature part 103. The first metal layer 131 may include a conductive pillar and/or a conductive trace. In addition, in addition to forming the first metal layer 131, the conductive interconnection structure 100 may also form a second metal layer 132 in another third opening 126 and a third metal layer 133 in the fourth opening 127. The second metal layer 132 and the third metal layer 133 may include another conductive pillar and/or another conductive trace, respectively.

Referring to FIGS. 10A to 10D, a plan view, a cross-sectional view along the A-A′ cross-sectional direction, a cross-sectional view along the B-B′ cross-sectional direction, and a cross-sectional view along the C-C′ cross-sectional direction of the conductive interconnection structure 100 are shown. The conductive interconnection structure 100 may include a conductive feature part 103, a dielectric structure 105, a trench filling portion 120, a via portion 128, and at least one metal layer 130. The dielectric structure 105 is formed over the conductive feature part 103. The dielectric structure 105 includes a first dielectric layer 107 and a second dielectric layer 108 stacked on each other. The second dielectric layer 108 covers the first dielectric layer 107. The trench filling portion 120 is embedded in the dielectric structure 105, and the trench filling portion 120 and the second dielectric layer 108 have different etching selectivities. The via portion 128 is located in the first dielectric layer 107 at the bottom surface of the trench filling portion 120.

The metal layer 130 may include a first metal layer 131, a second metal layer 130 and/or a third metal layer 133. As shown in FIG. 10A, the first metal layer 131 and the second metal layer 132 are spaced apart in the dielectric structure 105, and the width and the position of the via portions 128 of the first metal layer 131 and the second metal layer 132 are respectively defined by the trench filling portion 120 to avoid via-induced-metal-bridge (VIMB) problem between the adjacent first metal layer 131 and the second metal layer 132 due to the deviation of the opening position. In addition, the width and the position of the via portions 128 of the third metal layer 133 is defined by another trench filling portion 120 to avoid via-induced-metal-bridge (VIMB) problem between the adjacent second metal layer 132 and the third metal layer 133 due to the deviation of the opening position.

Referring to FIGS. 10B and 10C, the first metal layer 131 includes a first conductive pillar 131a and a first conductive trace 131b. The first conductive pillar 131a can penetrate the dielectric structure 105, the trench filling portion 120 and the via portion 128, and the bottom surface of the first conductive pillar 131a is electrically connected to the first conductive feature part 103. The first conductive trace 131b is vertically connected to one end of the first conductive pillar 131a, and the first conductive trace 131b is electrically connected to the first conductive feature part 103 through the first conductive pillar 131a. In addition, the second metal layer 132 may include a second conductive pillar 132a and a second conductive trace 132b, which are configured in the same manner as the first metal layer 131 and will not be described again here. In addition, referring to FIG. 10D, the third metal layer 133 includes a third conductive pillar 133a and a third conductive trace 133b. The third conductive pillar 133a can penetrate the dielectric structure 105, another trench filling portion 120 and the via portion 128, and the bottom surface of the third conductive pillar 133a is electrically connected to the third conductive feature part 103. The third conductive trace 133b is vertically connected to one end of the third conductive pillar 133a, and the third conductive trace 133b is electrically connected to the third conductive feature part 103 through the third conductive pillar 133a.

In FIGS. 10A to 10D, the via size along the A-A′ direction is defined by the width of the conductive trace. The via size along the B-B′ direction is defined by the width of the trench filling portion 120. In addition, the part of conductive trace connecting to via would cover the trench filling portion 120 on both sidewalls. If more than one via is simultaneously defined by one trench filling portion 120, the trench filling portion 120 would connect and exist between the parts of the conductive traces.

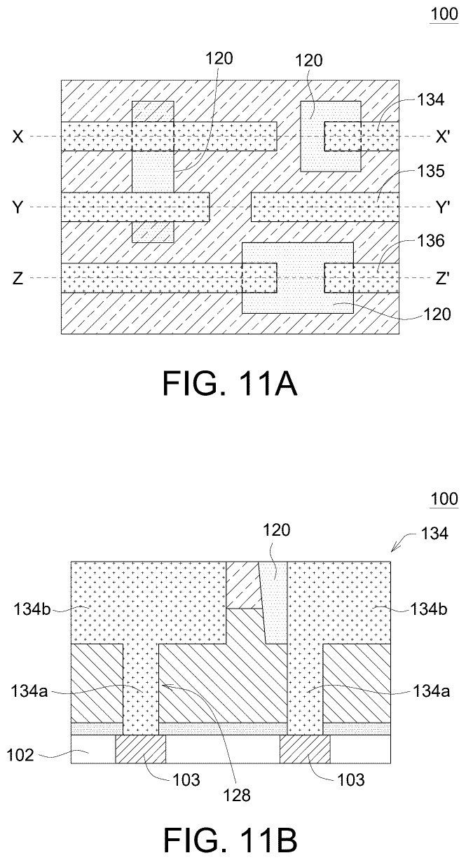

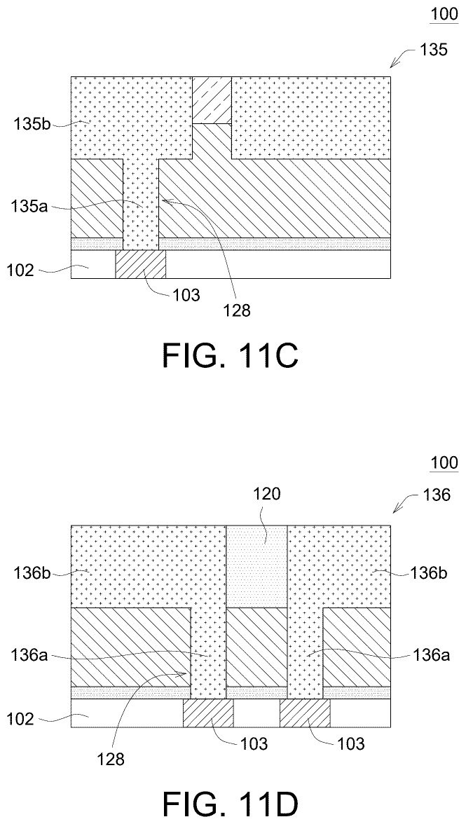

Referring to FIGS. 11A to 11D, a plan view, a cross-sectional view along the X-X′ cross-sectional direction, a cross-sectional view along the Y-Y′ cross-sectional direction, and a cross-sectional view along the Z-Z′ cross-sectional direction of the conductive interconnection structure 100 are shown. The conductive interconnection structure 100 may include a conductive feature part 103, a dielectric structure 105, a trench filling portion 120, a via portion 128, and at least one metal layer 130. As shown in FIG. 11A, the first metal layer 134, the second metal layer 135 and the third metal layer 136 are spaced apart in the dielectric structure 105, and the width and the position of the via portions 128 of the first metal layer 135, the second metal layer 135 and the third metal layer 136 are respectively defined by respective trench filling portion 120.

As shown in FIG. 11B, the first metal layer 134 is divided into two line segments. Each line segment includes a first conductive pillar 134a and a first conductive trace 134b. The first conductive pillar 134a can penetrate the dielectric structure 105, the trench filling portion 120 and the via portion 128, and the bottom surface of the first conductive pillar 131a is electrically connected to the first conductive feature part 103. In addition, as shown in FIG. 11C, the second metal layer 135 is divided into two line segments. One line segment may include a second conductive pillar 135a and a second conductive trace 135b, and the other line segment may include a conductive trace. The second conductive pillar 135a may penetrate the dielectric structure 105, the trench filling portion 120 and the via portion 128, and the bottom surface of the second conductive pillar 135a is electrically connected to the second conductive feature part 103.

In addition, referring to FIG. 11D, the third metal layer 136 is divided into two line segments. Each line segment includes a third conductive pillar 136a and a third conductive trace 136b. The third conductive pillar 136a may penetrate the dielectric structure 105, another trench filling portion 120 and the via portion 128, and the bottom surface of the third conductive pillar 136a is electrically connected to the third conductive feature part 103.

In FIGS. 11A-11D, the via size along the Z-Z′ and X-X′ directions is defined by the location and the deviation between the trench filling portion 120 and the end of each line segment, and there is no line end enclosure if the trench filling portion 120 overlays with the end of the line segment. In addition, the part of line segment connecting to via would cover the trench filling portion 120 on both sidewalls or have U-shaped sidewalls. When the trench filling portion 120 crosses over two parallel metal line, the trench filling portion 120 exists between the two metal lines. When the trench filling portion 120 crosses over the end of two line segments, the trench filling portion 120 exists between the two line segments.

In some embodiments, the metal layer 130 may be referred to as a metal-to-device (MD) or a metal-to-drain (MD) contact, which generally refers to a contact to the source/drain region or a contact to the gate structure. In some embodiments, the metal layer 130 may be formed without a liner layer, a barrier, a seed layer, or any interposer layer. Therefore, in these embodiments, the metal layer 130 may be in contact with the dielectric structure 105, but the present disclosure is not limited thereto.

The metal layer 130 can be formed in the dielectric structure 105 by a deposition process, such as an atomic layer deposition (ALD) process, an epitaxial growth process, a low pressure chemical vapor deposition (LPCVD) process and/or plasma enhanced chemical vapor deposition (PECVD) process. The metal layer 116 may be selected from a group consisting of TiN, TaN, copper (Cu), cobalt (Co), nickel (Ni), lead (Pb), gold (Au), rhenium (Re), iridium (Ir), titanium (Ti), Hafnium (Hf), platinum (Pt), ruthenium (Ru), aluminum (Al) and any combination of the above.

The present disclosure is related to a conductive interconnection structure and a manufacturing method thereof. A self-aligned via (SAV) patterning process can be achieved by fabricating a trench filling portion before a hard mask deposition for via definition, which can prevent via misaligned to metal trace. According to this approach, it provides a high-precision lithography overlay window for via portion, reduces via contact resistance by larger via contact area and prevents via contact area shrinkage, via open, and via-induced-metal-bridge (VIMB) caused by via overlay shift.

According to some embodiments of the present disclosure, a method of manufacturing a conductive interconnection structure includes the following steps. A dielectric structure is formed over a conductive feature part. The dielectric structure includes a first dielectric layer and a second dielectric layer stacked on top of each other. The second dielectric layer covers the first dielectric layer. The dielectric structure is etched to form a first opening in the dielectric structure. The first opening exposes a portion of the first dielectric layer. The first opening is used to define a depth and a width of a trench filling portion. A trench filling material is filled into the first opening to form the trench filling portion, and the etching selectivities of the trench filling material and the second dielectric layer is different. The trench filling portion is etched to form a second opening in the trench filling portion, and the second opening exposes the first dielectric layer located at the bottom surface of the trench filling portion. The exposed first dielectric layer is etched to form a third opening in the first dielectric layer. The third opening exposes the conductive feature. The third opening is used to define a depth and a width of a via portion. A metal layer is formed in the second opening and the third opening, and one end of the metal layer is electrically connected to the conductive feature part.

According to some embodiments of the present disclosure, a method of manufacturing a conductive interconnection structure includes the following steps. A first opening is formed in a dielectric structure. The first opening is used to define a depth and a width of a trench filling portion. A second opening is formed in the trench filling portion. The second opening is used to define a depth and width of a conductive trace to be formed. A third opening is formed in the dielectric structure located on a bottom surface of the trench filling portion. The third opening is used to define a depth and a width of a via portion. A metal layer is formed in the second opening and the third opening.

According to some embodiments of the present disclosure, a conductive interconnection structure includes a conductive feature part, a dielectric structure, a trench filling portion, a via portion and a metal layer. The dielectric structure is formed over the conductive feature part. The dielectric structure includes a first dielectric layer and a second dielectric layer stacked on each other. The second dielectric layer covers the first dielectric layer. The trench filling portion is embedded in the dielectric structure, and the trench filling portion and the second dielectric layer have different etching selectivities. The via portion is located in the first dielectric layer at the bottom surface of the trench filling portion. The metal layer penetrates the dielectric structure, the trench filling portion and the via portion, and one end of the metal layer is electrically connected to the conductive feature part.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a conductive interconnect ion structure, comprising:
forming a dielectric structure over a conductive feature part, the dielectric structure including a first dielectric layer and a second dielectric layer stacked on each other, the second dielectric layer covering on a top of the first dielectric layer;
etching the dielectric structure to form a first opening in the dielectric structure, the first opening exposing a portion of the first dielectric layer, and the first opening being used to define a depth and a width of a trench filling portion;
filling a trench filling material into the first opening to form the trench filling portion, the trench filling material and the second dielectric layer having different etching selectivities;
etching the trench filling portion to form a second opening in the trench filling portion, the second opening exposing the first dielectric layer located on a bottom surface of the trench filling portion;
etching the exposed first dielectric layer to form a third opening in the first dielectric layer, the third opening exposing the conductive feature part, and the third opening being used to define a depth and a width of a via portion; and
forming a metal layer in the second opening and the third opening, and one end of the metal layer being electrically connected to the conductive feature part.

2. The method of claim 1, further comprising forming a contact etch stop layer (CESL) on the conductive feature part before forming the dielectric structure, the contact etch stop layer (CESL) covering the first dielectric layer.

3. The method of claim 1, wherein an etch selectivity ratio of the second dielectric layer relative to the trench filling portion is greater than 5.

4. The method of claim 1, wherein the metal layer includes a conductive pillar that penetrates the dielectric structure, the trench filling portion and the via portion, and a bottom surface of the conductive pillar is electrically connected to the conductive feature part.

5. The method of claim 4, wherein the third opening is used to define the depth and width of the conductive pillar filling in the via portion.

6. The method of claim 4, wherein the metal layer further includes a conductive trace, the conductive trace is connected to one end of the conductive pillar, and the conductive trace is electrically connected to the conductive feature part through the conductive pillar.

7. The method of claim 6, wherein the second opening is used to define the depth and width of the conductive trace filling in the trench filling portion.

8. A method of manufacturing a conductive interconnect ion structure, comprising:
forming a first opening in a dielectric structure, the first opening being used to define a depth and a width of a trench filling portion;
forming a second opening in the trench filling portion, the second opening being used to define a depth and width of a conductive trace to be formed;
forming a third opening in the dielectric structure located on a bottom surface of the trench filling portion, the third opening being used to define a depth and a width of a via portion; and
forming a metal layer in the second opening and the third opening.

9. The method of claim 8, wherein the etching selectivity ratio of the dielectric structure relative to the trench filling portion is greater than 5.

10. The method of claim 8, wherein the metal layer includes a conductive pillar penetrating the dielectric structure, the trench filling portion and the via portion.

11. The method of claim 10, wherein the third opening is used to define a depth and a width of the conductive pillar filling in the via portion.

12. The method of claim 10, wherein the metal layer further includes the conductive trace, and the conductive trace is connected to one end of the conductive pillar.

13. The method of claim 12, wherein the second opening is used to define the depth and the width of the conductive trace filling in the trench filling portion.

14. A conductive interconnect ion structure, comprising:
a conductive feature part;
a dielectric structure formed over the conductive feature part, the dielectric structure including a first dielectric layer and a second dielectric layer stacked on each other, the second dielectric layer covering on a top of the first dielectric layer;
a trench filling portion embedded in the dielectric structure;
a via portion located in the first dielectric layer on a bottom surface of the trench filling portion; and
a metal layer penetrating the dielectric structure, the trench filling portion and the via portion, and one end of the metal layer being electrically connected to the conductive feature part.

15. The conductive interconnect ion structure of claim 14, wherein an etch selectivity ratio of the dielectric structure relative to the trench filling portion is greater than 5.

16. The conductive interconnect ion structure of claim 14, wherein the metal layer includes a conductive pillar, and a bottom surface of the conductive pillar is electrically connected to the conductive feature part.

17. The conductive interconnect ion structure of claim 16, wherein a depth and a width of the via portion are equal to the depth and width of the conductive pillar.

18. The conductive interconnect ion structure of claim 13, wherein the metal layer further includes a conductive trace connected to one end of the conductive pillar, and the conductive trace is electrically connected to the conductive feature part through the conductive pillar.

19. The conductive interconnect ion structure of claim 18, wherein a depth of the trench filling portion is equal to a depth of the conductive trace.

20. The conductive interconnect ion structure of claim 18, wherein the conductive feature part is a front-end-of-line (FEOL) or middle-end-of-line (MEOL) component.
